(19) United States
(12) Patent Application Publication
(10) Pub. No.: US 2017/0092375 A1
(43) Pub. Date: Mar. 30, 2017

(54) SHIFT REGISTER AND DRIVING METHOD THEREOF, AND GATE DRIVING CIRCUIT

(71) Applicants: Shanghai AVIC OPTO Electronics Co., Ltd., Shanghai (CN); Tianma Micro-Electronics Co., Ltd., Shenzhen (CN)

(72) Inventors: Zhiqiang Xia, Shanghai (CN); Dongliang Dun, Shanghai (CN); Huijun Jin, Shanghai (CN)

(21) Appl. No.: 15/003,315

(22) Filed: Jan. 21, 2016

(30) Foreign Application Priority Data
Sep. 30, 2015 (CN) 201510641846.8

(51) Int. Cl. G11C 19/28; G09G 3/36; G11C 5/14

(52) U.S. Cl. CPC G11C 19/28; G11C 5/147; G09G 3/3674; G09G 2310/0286; G09G 2320/0214

(57) ABSTRACT

A shift register, a driving method thereof, and a gate driving circuit. The shift register includes a first transistor, with a control terminal thereof electrically connected to a first control node; a scan driving unit; a reset unit; a maintaining control unit; a first potential maintaining unit, with a control terminal thereof electrically connected to a second control node, an input terminal thereof electrically connected to a third level signal line, and an output terminal thereof electrically connected to the first control node; and a second potential maintaining unit, with a first control terminal thereof electrically connected to the second control node, a second control terminal thereof electrically connected to a second clock signal line, an input terminal thereof electrically connected to a fourth level signal line, and an output terminal thereof electrically connected to the output terminal of the shift register.

### CROSS-REFERENCE TO RELATED APPLICATION

This application claims priority to Chinese Application No. 201510641846.8, filed Sep. 30, 2015, which is herein incorporated by reference in its entirety.

### TECHNICAL FIELD

The present disclosure relates to the field of liquid crystal display technology and, in particular, to a shift register and a driving method thereof, and a gate driving circuit.

### BACKGROUND

A display region and a peripheral region surrounding the display region are formed on an array substrate of a liquid crystal display device. Pixel units arranged in a matrix are disposed in the display region, each of the pixel units is controlled by a thin film transistor, and gates of all the thin film transistors controlling each row of pixel units are connected to a gate line, thus X gate lines lead out from the display region including X rows of the pixel units, where X is a positive integer. Further, a gate driving circuit, which is formed by sequentially connected cascaded shift registers, is disposed in the peripheral region of the array substrate. The cascaded shift registers are electrically connected to the X gate lines in a one-to-one correspondence. During operation, the cascaded shift registers sequentially output scanning signals to the corresponding gate lines.

In the related art, an N-type transistor is adopted in the shift register as an output control switch for the scanning signal. The N-type transistor is turned on when a high level is applied to the gate of the N-type transistor, such that a high level signal received by a source of the N-type transistor can be outputted from a drain of the N-type transistor as the scanning signal. In a period without an output of the scanning signal, the gate and drain of the N-type transistor are conductively connected with a low level signal line VGL, thus the N-type transistor is turned off and the output of the scanning signal is terminated. However, if the low levels having the equal potential are applied simultaneously to the gate and drain of the N-type transistor, a leakage current phenomenon occurs between the source and drain of the N-type transistor, causing a power loss. Due to a large number of the cascaded shift registers in the gate driving circuit, the power loss caused to the gate driving circuit is significant in the related art. Further, the same problem exists in the shift register adopting a P-type transistor.

### SUMMARY

Embodiments of the disclosure provide a shift register and a driving method thereof, and a gate driving circuit, for reducing the power loss of the shift register.

In a first example, embodiments of the disclosure provide a shift register, including:
a first transistor, wherein a gate of the first transistor is electrically connected with a first control node, a first electrode of the first transistor is electrically connected with a scanning signal input line, and a second electrode of the first transistor is electrically connected with an output terminal of the shift register;
a scan driving unit, wherein a control terminal of the scan driving unit is electrically connected with an output terminal of a preceding N-th shift register, an input terminal of the scan driving unit is electrically connected with a first level signal line, and an output terminal of the scan driving unit is electrically connected with the first control node to control a potential of the first control node to turn on the first transistor and output a scanning signal, wherein N is a positive integer;
a reset unit, wherein a control terminal of the reset unit is electrically connected with an output terminal of a succeeding M-th shift register, an input terminal of the reset unit is electrically connected with a second level signal line, and an output terminal of the reset unit is electrically connected with the first control node to control the potential of the first control node to turn off the first transistor, wherein M is a positive integer;
a maintaining control unit, wherein a control terminal of the maintaining control unit is electrically connected with the first control node, a first input terminal of the maintaining control unit is electrically connected with a third or fourth level signal line, a second input terminal of the maintaining control unit is electrically connected with a first clock signal line, and an output terminal of the maintaining control unit is electrically connected with a second control node to control a potential of the second control node;
a first potential maintaining unit, wherein a control terminal of the first potential maintaining unit is electrically connected with the second control node, an input terminal of the first potential maintaining unit is electrically connected with the third level signal line, and an output terminal of the first potential maintaining unit is electrically connected with the first control node; and
a second potential maintaining unit, wherein a first control terminal of the second potential maintaining unit is electrically connected with the second control node, a second control terminal of the second potential maintaining unit is electrically connected with a second clock signal line, an input terminal of the second potential maintaining unit is electrically connected with a fourth level signal line, and an output terminal of the second potential maintaining unit is electrically connected with the output terminal of the shift register;
wherein a polarity of a level signal outputted from the third level signal lines is identical to a polarity of a level signal outputted from the fourth level signal line, and an absolute value of the level signal outputted from the third level signal lines is greater than an absolute value of the level signal outputted from the fourth level signal line.

In a second example, embodiments of the disclosure provide a gate driving circuit including cascaded shift registers.

In a third example, embodiments of the disclosure further provide a method for driving the shift register, including:
a first period in which the scan driving unit controls a potential of a first control node to turn on the first transistor, the first control node is charged to raises the potential thereof;
a second period in which the first transistor is turned on to output the scanning signal from the scanning signal input line to the output terminal of the shift register;
a third period in which the reset unit controls a potential of the first control node to turn off the first transistor; and
a fourth period in which the first potential maintaining unit transmits a level signal from the third level single line to the first control node, the second potential maintaining unit transmits a level signal from the fourth level single line to the output terminal of the shift register, and the first transistor is maintained in a turned-off state.

In the technical solutions of the disclosure, the third level signal line and the fourth level signal line which are electrically connected with the input terminal of the first potential maintaining unit and the input terminal of the second potential maintaining unit, respectively, are provided, so that after the first transistor of the shift register outputs the scanning signal and is reset, the level signal provided by the third level signal line is applied to the gate of the first transistor via the first potential maintaining unit and the level signal provided by the fourth level signal line is applied to the second electrode of the first transistor via the second potential maintaining unit, where the polarity of the level signal outputted from the third level signal lines is identical to that of the level signal outputted from the fourth level signal line, and the absolute value of the level signal outputted from the third level signal lines is greater than that of the level signal outputted from the fourth level signal line. When the first transistor is embodied as the N-type transistor, the third and fourth level single lines are each configured to provide a low level signal, and the low level signal provided from the third level signal line is lower than that provided from the fourth level signal line, thereby eliminating the leakage current and decreasing the power loss. When the first transistor is embodied as the P-type transistor, the third and fourth level single lines are each configured to provide a high level signal, and the high level signal provided from the third level signal line is higher than that provided from the fourth level signal line, thereby eliminating the leakage current and decreasing the power loss.

While multiple embodiments are disclosed, still other embodiments of the disclosure will become apparent to those skilled in the art from the following detailed description, which shows and describes illustrative embodiments of the disclosure. Accordingly, the drawings and detailed description are to be regarded as illustrative in nature and not restrictive.

### BRIEF DESCRIPTION OF THE DRAWINGS

FIG. 1A is a schematic view showing a circuit of a shift register, according to embodiments of the disclosure;

FIG. 1B is a schematic diagram showing a variant of the circuit of the shift register, according to embodiments of the disclosure;

FIG. 2A is a schematic structural diagram showing a circuit of a shift register, according to embodiments of the disclosure;

FIG. 2B is a schematic structural diagram showing a variant of the circuit of the shift register, according to embodiments of the disclosure;

FIG. 3 is a schematic structural diagram showing a variant of the circuit of the shift register, according to embodiments of the disclosure;

FIG. 4 is a schematic diagram showing a leakage current versus a gate-drain voltage (i.e. a voltage across the gate and drain) of an N-type transistor, according to embodiments of the disclosure;

FIG. 5 is a schematic structural diagram showing yet another variant of the circuit of the shift register, according to embodiments of the disclosure;

FIG. 6 is a schematic structural diagram showing yet another variant of the circuit of the shift register, according to embodiments of the disclosure;

FIG. 7 is a schematic structural diagram showing a gate driving circuit, according to embodiments of the disclosure;

FIG. 8 is a flow chart showing a method for driving the shift register, according to embodiments of the disclosure; and

FIG. 9 is a schematic diagram showing a time sequence of driving the shift register, according to embodiments of the disclosure.

While the disclosure is amenable to various modifications and alternative forms, embodiments have been shown by way of example in the drawings and are described in detail below. The intention, however, is not to limit the disclosure to the particular embodiments described. On the contrary, the disclosure is intended to cover all modifications, equivalents, and alternatives falling within the scope of the disclosure as defined by the appended claims.

### DETAILED DESCRIPTION

The disclosure is described further in detail through embodiments in combination with the accompanying drawings below. It should be appreciated that the embodiments described herein are merely intended to explain but not limit the disclosure. It should be also noted that parts relating to the disclosure are shown in the accompanying drawings in a non-exhaustive way.

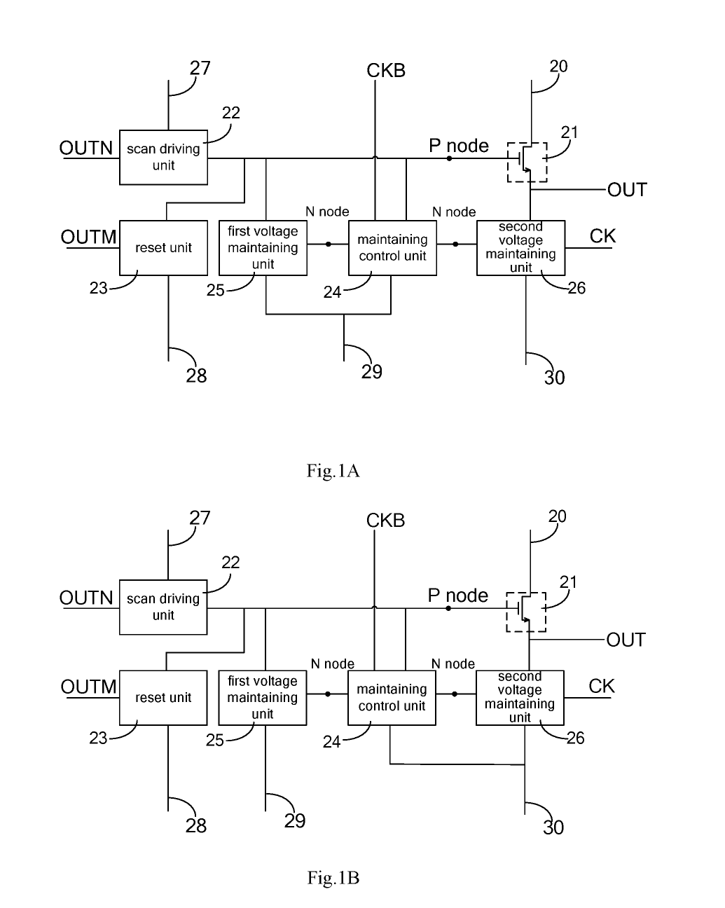

FIG. 1A is a schematic view showing a circuit of a shift register, according to embodiments of the disclosure. As shown in FIG. 1A, the shift register includes a first transistor 21, a scan driving unit 22, a reset unit 23, a maintaining control unit 24, a first potential maintaining unit 25 and a second potential maintaining unit 26.

A gate of the first transistor 21 is electrically connected with a first control node P node, a first electrode of the first transistor 21 is electrically connected with a scanning signal input line 20, and a second electrode of the first transistor 21 is electrically connected with an output terminal OUT of the shift register.

A control terminal of the scan driving unit 22 is electrically connected with an output terminal OUTN of the preceding N-th shift register, an input terminal of the scan driving unit 22 is electrically connected with a first level signal line 27, and an output terminal of the scan driving unit 22 is electrically connected with the first control node P node to control the potential of the first control node P node and hence to turn on the first transistor 21, thereby outputting a scanning signal, where N is a positive integer.

A control terminal of the reset unit 23 is electrically connected with an output terminal OUTN of the succeeding M-th shift register, an input terminal of the reset unit 23 is electrically connected with a second level signal line 28, and an output terminal of the reset unit 23 is electrically connected with the first control node P node to control the potential of the first control node P node to turn off the first transistor 21, where M is a positive integer. Typically, M is equal to N.

A control terminal of the maintaining control unit 24 is electrically connected with the first control node P node, a first input terminal of the maintaining control unit 24 is electrically connected with a third level signal line 29, a second input terminal of the maintaining control unit 24 is electrically connected with a first clock signal line CKB, and an output terminal of the maintaining control unit 24 is electrically connected with a second control node N node to control the potential of the second control node N node. In addition, as shown in FIG. 1B, the first input terminal of the maintaining control unit 24 may be alternatively electrically connected with a forth level signal line 30 in other embodiments.

A control terminal of the first potential maintaining unit 25 is electrically connected with the second control node N node, an input terminal of the first potential maintaining unit 25 is electrically connected with the third level signal line 29, and an output terminal of the first potential maintaining unit 25 is electrically connected with the first control node P node.

A first control terminal of the second potential maintaining unit 26 is electrically connected with the second control node N node, a second control terminal of the second potential maintaining unit 26 is electrically connected with a second clock signal line CK, an input terminal of the second potential maintaining unit 26 is electrically connected with a fourth level signal line 30, and an output terminal of the second potential maintaining unit 26 is electrically connected with the output terminal OUT of the shift register.

The polarity of the level signal outputted by the third level signal line 29 is identical to that of the level signal outputted by the fourth level signal line 30, and the absolute value of the level signal outputted by the third level signal line 29 is greater than that of the level signal outputted by the fourth level signal line 30.

In the case that the first transistor is embodied by an N-type transistor, a low level signal is provided by each of the third and fourth level signal lines 29 and 30, and the low level signal provided by the third level signal line 29 is lower than that provided by the fourth level signal line 30. When the low level signal provided by the third level signal line 29 is applied to the first control node P node (i.e. the gate of the N-type transistor) via the first potential maintaining unit 25, while the low level signal provided by the fourth level signal line 30 is applied to the second electrode of the N-type transistor via the second potential maintaining unit 26, the leakage current in the N-type transistor can be eliminated, thereby decreasing the power loss of the shift register. In the case that the first transistor is embodied by a P-type transistor, a high level signal is provided by each of the third and fourth level signal lines 29 and 30, and the high level signal provided by the third level signal line 29 is higher than that provided by the fourth level signal line 30. When the high level signal provided by the third level signal line 29 is applied to the first control node P node (i.e. the gate of the P-type transistor) via the first potential maintaining unit 25, while the high level signal provided by the fourth level signal line 30 is applied to the second electrode of the P-type transistor via the second potential maintaining unit 26, the leakage current in the P-type transistor is eliminated, thereby decreasing the power loss of the shift register.

Further, in the above embodiments of the disclosure, the first clock signal line CKB may be reused as the scanning signal input line 20, that is, a clock signal provided by the first clock signal line CKB is outputted to the first transistor 21 as the scanning signal, thereby reducing the number of wirings connected to the shift register. In this way, the clock signal provided by the first clock signal line CKB is not only used to control an action of the maintaining control unit, but also outputted to the first transistor 21 as the scanning signal in a scanning signal output period.

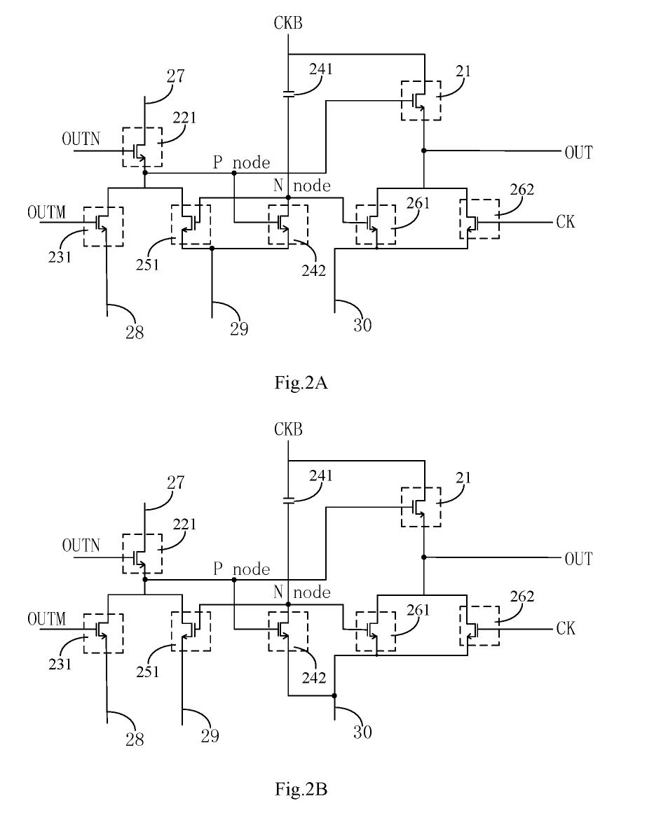

FIG. 2A is a schematic structural diagram showing a circuit of a shift register, according to embodiments of the disclosure. As shown FIG. 2A in combination with FIG. 1A, the scan driving unit 22 includes a second transistor 221. A gate of the second transistor 221 is electrically connected with the output terminal OUTN of the preceding N-th shift register, a first electrode of the second transistor 221 is electrically connected with the first level signal line 27, and a second electrode of the second transistor 221 is electrically connected with the first control node P node.

The reset unit 23 includes a third transistor 231. A gate of the third transistor 231 is electrically connected with the output terminal OUTN of the succeeding M-th shift register, a first electrode of the third transistor 231 is electrically connected with the second level signal line 28, and a second electrode of the third transistor 231 is electrically connected with the first control node P node.

The maintaining control unit 24 includes a first capacitor 241 and a fourth transistor 242. A first electrode of the first capacitor 241 is electrically connected with the first clock signal line CKB, a second electrode of the first capacitor 241 is electrically connected with the second control node N node, a gate of the fourth transistor 242 is electrically connected with the first control node P node, a first electrode of the fourth transistor 242 is electrically connected with the third level signal line 29, and a second electrode of the fourth transistor 242 is electrically connected with the second control node N node.

The first potential maintaining unit 25 includes a fifth transistor 251. A gate of the fifth transistor 251 is electrically connected with the second control node N node, a first electrode of the fifth transistor 251 is electrically connected with the third level signal line 29, and a second electrode of the fifth transistor 251 is electrically connected with the first control node P node.

The second potential maintaining unit 26 includes a sixth transistor 261 and a seventh transistor 262. A gate of the sixth transistor 261 is electrically connected with the second control node N node, a first electrode of the sixth transistor 261 is electrically connected with the fourth level signal line 30, and a second electrode of the sixth transistor 261 is electrically connected with the output terminal OUT of the shift register. A gate of the seventh transistor 262 is electrically connected with the second clock signal line CK, a first electrode of the seventh transistor 262 is electrically connected with a fourth level signal line 30, and a second electrode of the seventh transistor 262 is electrically connected with the output terminal OUT of the shift register.

In some embodiments, as shown in FIG. 2B based on FIG. 1B, the first electrode of the fourth transistor 242 of the maintaining control unit 24 is electrically connected with the fourth level signal line 30, and a second electrode of the fourth transistor 242 is electrically connected with the second control node N node. Unlike the embodiments of FIG. 2B, in the embodiments of FIG. 2A, when the fourth transistor 242 is turned on under the control of the first control node P node, the level signal provided by the third level signal line 29 is applied to the gate of the sixth transistor 261 in the second potential maintaining unit 26, and the level single provided by the fourth level signal line 30 is applied to the first electrode of the sixth transistor 261 in the second potential maintaining unit 26. The polarity of the level signal outputted by the third level signal line 29 is identical to that of the level signal outputted by the fourth level signal line 30, and the absolute value of the level signal outputted by the third level signal line 29 is greater than that of the level signal outputted by the fourth level signal line 30, that is, when the first transistor is embodied by an N-type transistor, the low level signal provided by the third level signal line 29 is lower than that provided by the fourth level signal line 30, so that the leakage current in the N-type transistor is eliminated, thereby decreasing the power loss of the shift register; when the first transistor is embodied by a P-type transistor, the high level signal provided by the third level signal line 29 is higher than that provided by the fourth level signal line 30, so that the leakage current in the P-type transistor is eliminated, thereby decreasing the power loss of the shift register;

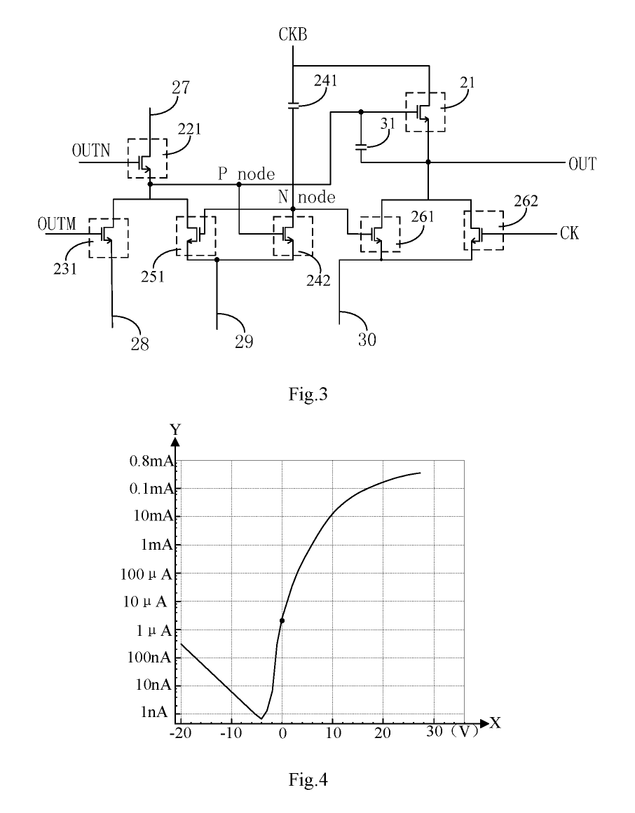

FIG. 3 is a schematic structural diagram showing a variant of the circuit of the shift register, according to embodiments of the disclosure. As shown in FIG. 3 on the basis of the circuit structure shown in FIG. 2A, the shift register, according to embodiments of the disclosure, further includes a second capacitor 31. A first electrode of the second capacitor 31 is electrically connected with the first control node P node, and a second electrode of the second capacitor 31 is electrically connected with the output terminal OUT of the shift register. In the scanning signal output period, when the scanning signal is outputted from the output terminal OUT of the shift register, for example, when the scanning signal of the high level is outputted from the output terminal OUT of the shift register if the first transistor 21 is an N-type transistor, the second capacitor maintains the high potential at the first control node P node, or when the scanning signal of the low level is outputted from the output terminal OUT of the shift register if the first transistor 21 is a P-type transistor, the second capacitor maintains the low potential at the first control node P node, thereby ensuring that the second transistor 21 is turned on.

Moreover, in the embodiments shown in FIG. 2A, FIG. 2B and FIG. 3, the first, second, third, fourth, fifth, sixth and seventh transistors 21, 221, 231, 242, 251, 261 and 262 are N-type transistors, in this case, a first high level signal is outputted from the first level signal line 27, a first low level signal is outputted from the second level signal line 28, a second low level signal is outputted from the third level signal line 29, a third low level signal is outputted from the fourth level signal line 30, and a positive pulse signal is outputted from each of the first and second clock signal lines CKB and CK. Optionally, a time sequence of the signal outputted from the first clock signal line is opposite to that of the signal outputted from the second clock signal line.

In the various embodiments according to the disclosure, the high level signal represents a positive voltage signal as outputted, and the low level signal represents a negative voltage signal as outputted. When the above-described transistors are N-type transistors, the second low level signal ranges from −10V to −17V, the third low level signal ranges from −5V to −12V, and the second low level signal provided to each shift register is always lower than the third low level signal in the application instance of the disclosure.

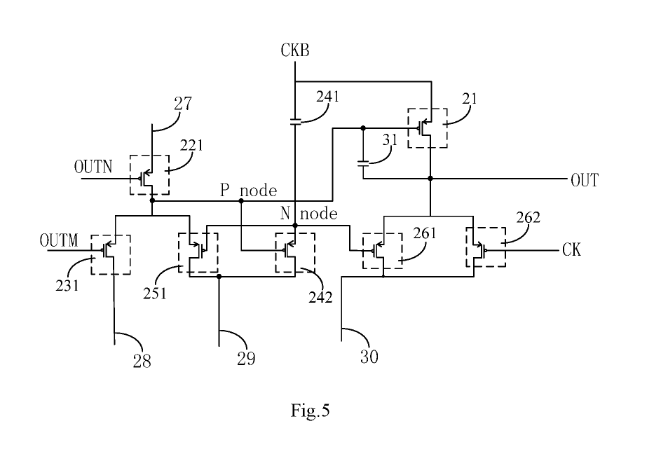

FIG. 4 is a schematic diagram showing a leakage current versus a gate-drain voltage of an N-type transistor, according to embodiments of the disclosure. The abscissa (X) represents a gate-drain voltage Vgs, i.e., a voltage between the gate and the drain (i.e., the second electrode of the first transistor) of the first transistor in the above embodiments, and a value of the gate-drain voltage is obtained as the gate voltage (i.e. voltage at the gate) Vg subtracted by the drain voltage (i.e. voltage at the drain) Vs, i.e., Vgs=Vg-Vs. The ordinate (Y) represents the leakage current. As shown in FIG. 4, when the gate potential of the first transistor is equal to the potential at the second electrode of the first transistor, i.e., when the gate-drain voltage Vgs is 0V, the leakage current is approximately 1.8 μA. When the gate potential of the first transistor 21 is even lower than the drain potential of the first transistor 21, i.e., when gate-drain voltage Vgs is less than 0, the leakage current gradually decreases, and decreases to the minimum level below 1 nA when Vgs=−4V (for example when the gate voltage Vg is −12V and the drain voltage Vs is −8V), as such, the power loss caused by the leakage current can be decreased efficiently by using the technical solution provided by the embodiments of the disclosure.

FIG. 5 is a schematic structural diagram showing yet another variant of the circuit of the shift register, according to embodiments of the disclosure. Unlike the shift register shown in FIG. 3, as shown in FIG. 5, the first, second, third, fourth, fifth, sixth and seventh transistors 21, 221, 231, 242, 251, 261 and 262 are P-type transistors, in this case, a fourth low level signal is outputted from the first level signal line 27, a second high level signal is outputted from the second level signal line 28, a third high level signal is outputted from the third level signal line 29, a fourth high level signal is outputted from the fourth level signal line 30, and a negative pulse signal is outputted from each of the first and second clock signal lines CKB and CK. Optionally, a time sequence of the signal outputted from the first clock signal line is opposite to that of the signal outputted from the second clock signal line.

In embodiments of FIG. 5, the high level signal ranges from 5V to 20V, the low level signal ranges from −15V to −5V, the third high level signal applied to the first transistor ranges from 10V to 17V, and the fourth high level signal applied to the first transistor ranges from 5V to 12V. Optionally, the voltage difference between the gate and the second electrode can be maintained at approximately 5V when the first transistor is turned off, thereby achieving the optimal effect of prevention of the leakage current.

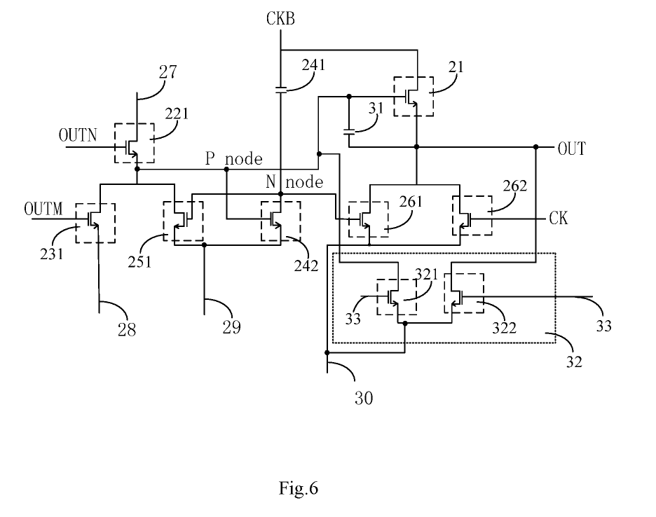

FIG. 6 is a schematic structural diagram showing yet another variant of the circuit of the shift register, according to embodiments of the disclosure. Based on the shift register shown in FIG. 3, the shift register as shown in FIG. 6 further includes a reset module 32. A control terminal of the reset module 32 is electrically connected with a reset signal line 33, an input terminal of the reset module 32 is electrically connected with the fourth level signal line 30, a first output terminal of the reset module 32 is electrically connected with the first control node P node, and a second output terminal of the reset module 32 is electrically connected with an output terminal OUT of the shift register.

In embodiments of the reset module 32, the reset module 32 includes an eighth transistor 321 and a ninth transistor 322. A gate of the eighth transistor 321 is electrically connected with the reset signal line 33, a first electrode of the eighth transistor 321 is electrically connected with the fourth level signal line 30, and a second electrode of the eighth transistor 321 is electrically connected with the first control node P node. A gate of the ninth transistor 322 is electrically connected with the reset signal line 33, a first electrode of the ninth transistor 322 is electrically connected with the fourth level signal line 30, and a second electrode of the ninth transistor 322 is electrically connected with the output terminal OUT of the shift register.

As such, the reset signal line 33 is directly connected with the gates of the eighth and ninth transistors 321 and 322 to directly control the turning on of the eighth and ninth transistors 321 and 322, such that the level signal provided by the fourth level signal line 30 is applied to the gate of the first transistor 21 and the output terminal OUT of the shift register so as to control the first transistor 21 to be at a turned-on state, and the level signal provided by the fourth level signal line 30 is outputted from the output terminal of the shift register, thereby resetting the shift register.

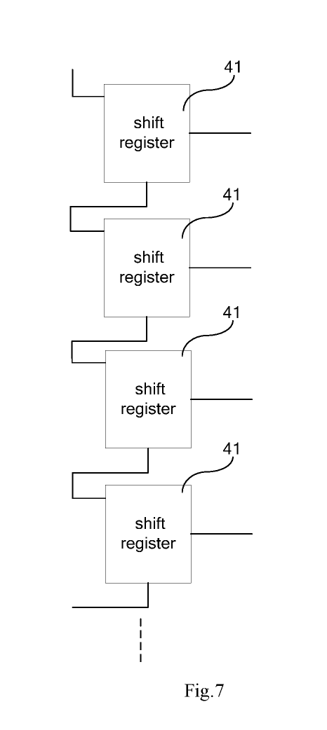

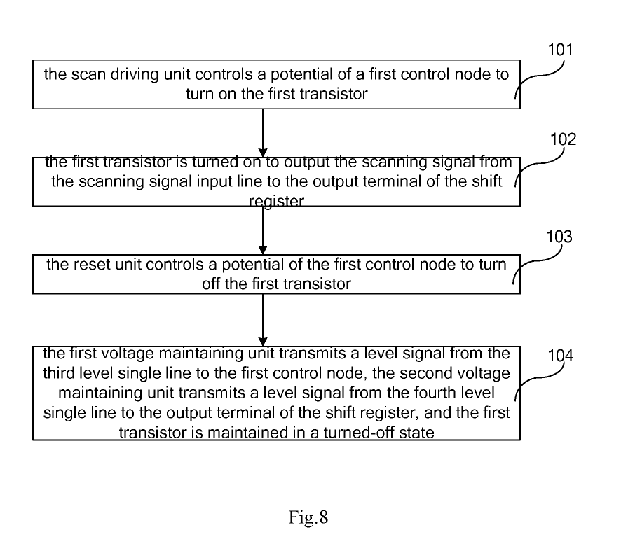

The disclosure further provides a gate driving circuit. FIG. 7 is a schematic structural diagram showing a gate driving circuit, according to embodiments of the disclosure. As shown in FIG. 7, the gate driving circuit includes a plurality of cascaded shift registers 41, each of which can be any one described in the above embodiments.

In the gate driving circuit, according to embodiments of the disclosure, since the third level signal line which is electrically connected with the input terminal of the first potential maintaining unit and the fourth level signal line which is electrically connected with the input terminal of the second potential maintaining unit are adopted in the shift register, after the first transistor of the shift register outputs the scanning signal and is reset, the level signal provided by the third level signal line is applied to the gate of the first transistor via the first potential maintaining unit and the level signal provided by the fourth level signal line is applied to the second electrode of the first transistor via the second potential maintaining unit, where the polarity of the level signal outputted from the third level signal lines is identical to that of the level signal outputted from the fourth level signal line, and the absolute value of the level signal outputted from the third level signal lines is greater than that of the level signal outputted from the fourth level signal line. When the first transistor is embodied as the N-type transistor, a low level signal is provided by each of the third and fourth level single lines, and the low level signal provided by the third level signal line is lower than that provided by the fourth level signal line, thereby eliminating the leakage current and decreasing the power loss. When the first transistor is embodied as the P-type transistor, a high level signal is provided by each of the third and fourth level single lines, and the high level signal provided by the third level signal line is higher than that provided by the fourth level signal line, thereby eliminating the leakage current and reducing the power loss.

Embodiments of the disclosure further provide a method for driving the shift register showed in any of FIG. 1A, FIG. 2A, FIG. 3, FIG. 5 and FIG. 6. FIG. 8 is a flow chart showing a method for driving the shift register, according to embodiments of the disclosure. As shown in FIG. 8, the method includes the following steps 101, 102, 103 and 104.

At Step 101, a scan driving unit 22 controls the potential of a first control node P node to turn on a first transistor 21.

At Step 102, the first transistor 21 is turned on so that the scanning signal received from the scanning signal input line 20 is outputted from the output terminal of the shift register.

At Step 103, the reset unit 23 controls the potential of the first control node P node to turn off the first transistor 21.

At Step 104, the first potential maintaining unit 25 transmits the level signal received from the third level single line 29 to the first control node P node, the second potential maintaining unit 26 transmits the level signal received from the fourth level single line 30 to the output terminal of the shift register, and the first transistor 21 remains at a turned-off state. In this step, when the first transistor 21 maintains its turned-off state, the voltage of the gate of the first transistor 21 is provided by the third level signal line 29, and the voltage of the second electrode of the first transistor 21, which is electrically connected with the output terminal of the shift register, is provided by the fourth level signal line 30, where the polarity of the level signal outputted by the third level signal line 29 is identical to that of the level signal outputted by the fourth level signal line 30, and the absolute value of the level signal outputted by the third level signal line 29 is greater than that of the level signal outputted by the fourth level signal line 30, thereby avoiding efficiently the power loss.

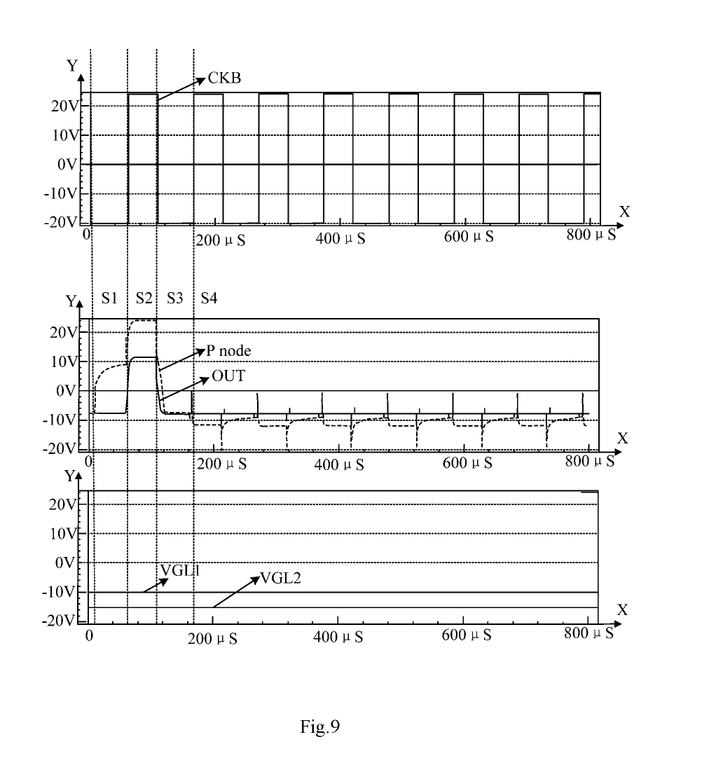

Referring to the circuit structure of the shift register shown in FIG. 3, for example, the method for driving the shift register is described below in the case where the various transistors of the shift register are embodied as N-type transistors. Here, a first high level signal is outputted from the first level signal line 27, a first low level signal is outputted from the second level signal line 28, a second low level signal is outputted from the third level signal line 29, a third low level signal is outputted from the fourth level signal line 30, and a positive pulse signal is outputted from each of the first and second clock signal lines CKB and CK. FIG. 9 is a schematic diagram showing a time sequence of driving the shift register, according to embodiments of the disclosure. The abscissa (X) represents time, and the ordinate (Y) represents potential. As shown in FIG. 9, the time sequence includes periods S1, S2, S3 and S4 below.

The first period S1 corresponds to the step 101 shown in FIG. 8, where the high level signal is outputted from the output terminal OUTN of the preceding N-th shift register, and the second transistor 221 is turned on. The first high level signal from the first level signal line 27 raises gradually the potential of the first control node P node. At this time, no pulse signal is inputted by the first clock signal line CKB and the second control node is at a low potential, and hence the first, third, fourth, fifth and sixth transistors 21, 231, 242, 251 and 261 are in the turned-off state, whereas a high level signal is inputted by the second clock signal line CK, and hence the seventh transistor 262 is turned on. Therefore, the third low level signal outputted from the fourth level signal line 30 is outputted to the output terminal of the shift register. The first period S1 can be also referred as a charging period of the first control node P node.

The second period S2 corresponds to the step 102 shown in FIG. 8, where since the first high level signal raises gradually the potential of the first control node P node, the first transistor 21 is eventually turned on. At this time, a high level signal is inputted by the first clock signal line CKB and is outputted from the output terminal of the shift register as the scanning signal. In this period, the first control node P node is at a high potential and the fourth transistor 242 is turned on such that the second low level signal from the third level signal line 29 is applied to the second control node N node, and the third, fifth and sixth transistors 231, 251 and 261 are still at the turned-off state. The second period S2 can also be referred as the scanning signal output period.

The third period S3 corresponds to the step 103 shown in FIG. 8, where a high level signal is outputted from the output terminal OUTN of the succeeding M-th shift register, and the third transistor 231 is turned on. Thus, the first low level signal inputted by the second level signal line 27 is applied to the first control node to decrease the potential of the first control node, and hence the first transistor 21 is turned off. This third period S3 can also be referred as a reset period.

The fourth period S4 corresponds to the step 104 shown in FIG. 8, where the first and second clock signal lines CKB and CK alternatively output the high level signal. When the high level signal is outputted from the first clock signal line CKB, the potential of the second control node N node is increased and the fifth and sixth transistors 251 and 261 are turned on, at this time, the second low level signal from the third level signal line 29 is applied to the first control node P node, i.e., the gate of the first transistor, while the third low level signal from the fourth level signal line 30 is inputted to the output terminal OUT of the shift register, i.e., the second electrode of the first transistor. When the high level signal is outputted from the second clock signal line CK, the seventh transistor 262 is turned on, thus the third low level signal from the fourth level signal line 30 is inputted to the output terminal OUT of the shift register, while the second, third and fifth transistors 221, 231 and 251 are placed in the turned-off state, and the potential of the first control node P node remains substantially unchanged. Therefore, in the fourth period, the potential of the gate of the first transistor can always be maintained as lower than the potential of the second electrode of the first transistor, so that the first transistor is maintained at the turned-off state and the leakage current thereof is insignificant, thereby decreasing the power loss. This period can also be referred as a stable output period.

The above embodiments are described by an example where the various transistors of the shift register are embodied as N-type transistors. However, as shown in FIG. 6, when the various transistors of the shift register are embodied as P-type transistors, a fourth low level signal is outputted from the first level signal line 27, a second high level signal is outputted from the second level signal line 28, a third high level signal is outputted from the third level signal line 29, a fourth high level signal is outputted from the fourth level signal line 30, and a negative pulse signal is outputted from each of the first and second clock signal lines CKB and CK. In this case, the time sequence includes a first period, a second period, a third period and a fourth period as follows.

At the first period which corresponds to the step 101 shown in FIG. 8, the low level signal is outputted from the output terminal OUTN of the preceding N-th shift register, and the second transistor 221 is turned on. The fourth low level signal from the first level signal line 27 decreases gradually the potential of the first control node P node. At this time, no pulse signal is inputted by the first clock signal line CKB and the second control node is at a high potential, and hence the first, third, fourth, fifth and sixth transistors 21, 231, 242, 251 and 261 are in the turned-off state, whereas a low level signal is inputted by the second clock signal line CK, and hence the seventh transistor 262 is turned on. Therefore, the third high level signal outputted from the fourth level signal line 30 is outputted to the output terminal of the shift register. The first period can also be referred as a discharging period of the first control node P node.

At the second period which corresponds to the step 102 shown in FIG. 8, since the fourth low level signal decreases gradually the potential of the first control node P node, the first transistor 21 is eventually turned on. At this time, a low level signal is inputted by the first clock signal line CKB and is outputted from the output terminal of the shift register as the scanning signal. In this period, the first control node P node is at a low potential and the fourth transistor 242 is turned on such that the third high level signal from the third level signal line 29 is applied to the second control node N node, and the third, fifth and sixth transistors 231, 251 and 261 are still in the turned-off state. The second period can also be referred as the scanning signal output period.

At the third period which corresponds to the step 103 shown in FIG. 8, a low level signal is outputted from the output terminal OUTN of the succeeding M-th shift register, and hence the third transistor 231 is turned on. Thus, the second high level signal from the second level signal line is applied to the first control node to raise the potential of the first control node, and hence the first transistor 21 is turned off. This third period can also be referred as the reset period.

At the fourth period which corresponds to the step 104 shown in FIG. 8, the first and second clock signal lines CKB and CK alternatively output the low level signal. When the low level signal is outputted from the first clock signal line CKB, the potential of the second control node N node is decreased and the fifth and sixth transistors 251 and 261 are turned on, at this time, the third high level signal from the third level signal line 29 is applied to the first control node P node, i.e., the gate of the first transistor, while the fourth high level signal from the fourth level signal line 30 is inputted to the output terminal OUT of the shift register, i.e., the second electrode of the first transistor. When the low level signal is outputted from the second clock signal line CK, the seventh transistor 262 is turned on, thus the fourth high level signal from the fourth level signal line 30 is inputted to the output terminal OUT of the shift register, while the second, third and fifth transistors 221, 232 and 251 are in the turned-off state, and the potential of the first control node P node remains substantially unchanged. Therefore, in the fourth period, the potential of the gate of the first transistor 21 can always be maintained as higher than the potential of the second electrode of the first transistor 21, so that the first transistor is maintained at the turned-off state and the leakage current thereof is insignificant, thereby decreasing the power loss. This period can be referred as the stable output period.

The above are embodiments and adopted technical principles of the disclosure. Those skilled in the art will appreciate that the disclosure is not limited to the specific embodiments described herein, and various obvious variations, readjustments and substitutions can be made without departing from the protection scope of the disclosure. Thus, although the disclosure has been described in detail in combination with the above embodiments, the disclosure is not limited to the above embodiments, and other embodiments can be made without departing from the scope of the disclosure as defined by the claims.

Various modifications and additions can be made to the exemplary embodiments discussed without departing from the scope of the disclosure. For example, while the embodiments described above refer to particular features, the scope of this disclosure also includes embodiments having different combinations of features and embodiments that do not include all of the described features. Accordingly, the scope of the disclosure is intended to embrace all such alternatives, modifications, and variations as fall within the scope of the claims, together with all equivalents thereof.

We claim:

1. A shift register, comprising:
a first transistor, wherein a gate of the first transistor is electrically connected with a first control node, a first electrode of the first transistor is electrically connected with a scanning signal input line, and a second electrode of the first transistor is electrically connected with an output terminal of the shift register;
a scan driving unit, wherein a control terminal of the scan driving unit is electrically connected with an output terminal of a preceding N-th shift register, an input terminal of the scan driving unit is electrically connected with a first level signal line, and an output terminal of the scan driving unit is electrically connected with the first control node to control a potential of the first control node to turn on the first transistor and output a scanning signal, wherein N is a positive integer;
a reset unit, wherein a control terminal of the reset unit is electrically connected with an output terminal of a succeeding M-th shift register, an input terminal of the reset unit is electrically connected with a second level signal line, and an output terminal of the reset unit is electrically connected with the first control node to control the potential of the first control node to turn off the first transistor, wherein M is a positive integer;
a maintaining control unit, wherein a control terminal of the maintaining control unit is electrically connected with the first control node, a first input terminal of the maintaining control unit is electrically connected with a third or fourth level signal line, a second input terminal of the maintaining control unit is electrically connected with a first clock signal line, and an output terminal of the maintaining control unit is electrically connected with a second control node to control a potential of the second control node;
a first potential maintaining unit, wherein a control terminal of the first potential maintaining unit is electrically connected with the second control node, an input terminal of the first potential maintaining unit is electrically connected with the third level signal line, and an output terminal of the first potential maintaining unit is electrically connected with the first control node; and
a second potential maintaining unit, wherein a first control terminal of the second potential maintaining unit is electrically connected with the second control node, a second control terminal of the second potential maintaining unit is electrically connected with a second clock signal line, an input terminal of the second potential maintaining unit is electrically connected with a fourth level signal line, and an output terminal of the second potential maintaining unit is electrically connected with the output terminal of the shift register;
wherein a polarity of a level signal outputted from the third level signal lines is identical to a polarity of a level signal outputted from the fourth level signal line, and an absolute value of the level signal outputted from the third level signal lines is greater than an absolute value of the level signal outputted from the fourth level signal line.

2. The shift register of claim 1, wherein the first clock signal line is reused as the scanning signal input line.

3. The shift register of claim 1, wherein the scan driving unit comprises a second transistor, and a gate of the second transistor is electrically connected with the output terminal of the preceding N-th shift register, a first electrode of the second transistor is electrically connected with the first level signal line, and a second electrode of the second transistor is electrically connected with the first control node;
the reset unit comprises a third transistor, wherein a gate of the third transistor is electrically connected with the output terminal of the succeeding M-th shift register, a first electrode of the third transistor is electrically connected with the second level signal line, and a second electrode of the third transistor is electrically connected with the first control node;
the maintaining control unit comprises a first capacitor and a fourth transistor, wherein a first electrode of the first capacitor is electrically connected with the first clock signal line, a second electrode of the first capacitor is electrically connected with the second control node, a gate of the fourth transistor is electrically connected with the first control node, a first electrode of the fourth transistor is electrically connected with the third or fourth level signal line, and a second electrode of the fourth transistor is electrically connected with the second control node;
the first potential maintaining unit comprise a fifth transistor, wherein a gate of the fifth transistor is electrically connected with the second control node, a first electrode of the fifth transistor is electrically connected with the third level signal line, and a second electrode of the fifth transistor is electrically connected with the first control node; and
the second potential maintaining unit comprises a sixth transistor and a seventh transistor, wherein a gate of the sixth transistor is electrically connected with the second control node, a first electrode of the sixth transistor is electrically connected with the fourth level signal line, a second electrode of the sixth transistor is electrically connected with the output terminal of the shift register, a gate of the seventh transistor is electrically connected with the second clock signal line, a first electrode of the seventh transistor is electrically connected with a fourth level signal line, and a second electrode of the seventh transistor is electrically connected with the output terminal of the shift register.

4. The shift register of claim 3, further comprising a second capacitor, wherein a first electrode of the second capacitor is electrically connected with the first control node, and a second electrode of the second capacitor is electrically connected with the output terminal of the shift register.

5. The shift register of claim 3, wherein the first, second, third, fourth, fifth, sixth and seventh transistors are N-type transistors; or the first, second, third, fourth, fifth, sixth and seventh transistors are P-type transistors.

6. The shift register of claim 5, wherein the first, second, third, fourth, fifth, sixth and seventh transistors are N-type transistors, the first level signal line is configured to output a first high level signal, the second level signal line is configured to output a first low level signal, the third level signal line is configured to output a second low level signal, the fourth level signal line is configured to output a third low level signal, and the first and second clock signal lines are each configured to output a positive pulse signal.

7. The shift register of claim 6, wherein the second low level signal ranges from −17V to −10V, and the third low level signal ranges from −12V to −5V.

8. The shift register of claim 5, wherein the first, second, third, fourth, fifth, sixth and seventh transistors are P-type transistors, the first level signal line is configured to output a fourth low level signal, the second level signal line is configured to output a second high level signal, the third level signal line is configured to output a third high level signal, the fourth level signal line is configured to output a fourth high level signal, and the first and second clock signal lines are each configured to output a negative pulse signal.

9. The shift register of claim 8, wherein the third high level signal ranges from 10V to 17V, and the fourth high level signal ranges from 5V to 12V.

10. The shift register of claim 1, further comprising a reset module, wherein a control terminal of the reset module is electrically connected with a reset signal line, an input terminal of the reset module is electrically connected with the fourth level signal line, a first output terminal of the reset module is electrically connected with the first control node, and a second output terminal of the reset module is electrically connected with the output terminal of the shift register.

11. The shift register of claim 10, wherein the reset module comprises an eighth transistor and a ninth transistor, a gate of the eighth transistor is electrically connected with the reset signal line, a first electrode of the eighth transistor is electrically connected with the fourth level signal line, and a second electrode of the eighth transistor is electrically connected with the first control node; a gate of the ninth transistor is electrically connected with the reset signal line, a first electrode of the ninth transistor is electrically connected with the fourth level signal line, and a second electrode of the ninth transistor is electrically connected with the output terminal of the shift register.

12. A gate driving circuit, comprising cascaded shift registers, wherein each of the shift registers comprises:
a first transistor, wherein a gate of the first transistor is electrically connected with a first control node, a first electrode of the first transistor is electrically connected with a scanning signal input line, and a second electrode of the first transistor is electrically connected with an output terminal of the shift register;
a scan driving unit, wherein a control terminal of the scan driving unit is electrically connected with an output terminal of preceding N-th shift register, an input terminal of the scan driving unit is electrically connected with a first level signal line, and an output terminal of the scan driving unit is electrically connected with the first control node to control a potential of the first control node to turn on the first transistor and output a scanning signal, wherein N is a positive integer;
a reset unit, wherein a control terminal of the reset unit is electrically connected with an output terminal of succeeding M-th shift register, an input terminal of the reset unit is electrically connected with a second level signal line, and an output terminal of the reset unit is electrically connected with the first control node to control the potential of the first control node to turn off the first transistor, wherein M is a positive integer;
a maintaining control unit, wherein a control terminal of the maintaining control unit is electrically connected with the first control node, a first input terminal of the maintaining control unit is electrically connected with a third or fourth level signal line, a second input terminal of the maintaining control unit is electrically connected with a first clock signal line, and an output terminal of the maintaining control unit is electrically connected with a second control node to control a potential of the second control node;
a first potential maintaining unit, wherein a control terminal of the first potential maintaining unit is electrically connected with the second control node, an input terminal of the first potential maintaining unit is electrically connected with the third level signal line, and an output terminal of the first potential maintaining unit is electrically connected with the first control node; and
a second potential maintaining unit, wherein a first control terminal of the second potential maintaining unit is electrically connected with the second control node, a second control terminal of the second potential maintaining unit is electrically connected with a second clock signal line, an input terminal of the second potential maintaining unit is electrically connected with a fourth level signal line, and an output terminal of the second potential maintaining unit is electrically connected with the output terminal of the shift register;
wherein a polarity of a level signal outputted from the third level signal lines is identical to a polarity of a level signal outputted from the fourth level signal line, and an absolute value of the level signal outputted from the third level signal lines is greater than an absolute value of the level signal outputted from the fourth level signal line.

13. A method for driving a shift register, wherein the shift register comprises:
a first transistor, wherein a gate of the first transistor is electrically connected with a first control node, a first electrode of the first transistor is electrically connected with a scanning signal input line, and a second electrode of the first transistor is electrically connected with an output terminal of the shift register;
a scan driving unit, wherein a control terminal of the scan driving unit is electrically connected with an output terminal of preceding N-th shift register, an input terminal of the scan driving unit is electrically connected with a first level signal line, and an output terminal of the scan driving unit is electrically connected with the first control node to control a potential of the first control node to turn on the first transistor and output a scanning signal, wherein N is a positive integer;
a reset unit, wherein a control terminal of the reset unit is electrically connected with an output terminal of succeeding M-th shift register, an input terminal of the reset unit is electrically connected with a second level signal line, and an output terminal of the reset unit is electrically connected with the first control node to control the potential of the first control node to turn off the first transistor, wherein M is a positive integer;
a maintaining control unit, wherein a control terminal of the maintaining control unit is electrically connected with the first control node, a first input terminal of the maintaining control unit is electrically connected with a third or fourth level signal line, a second input terminal of the maintaining control unit is electrically connected with a first clock signal line, and an output terminal of the maintaining control unit is electrically connected with a second control node to control a potential of the second control node;
a first potential maintaining unit, wherein a control terminal of the first potential maintaining unit is electrically connected with the second control node, an input terminal of the first potential maintaining unit is electrically connected with the third level signal line, and an output terminal of the first potential maintaining unit is electrically connected with the first control node; and
a second potential maintaining unit, wherein a first control terminal of the second potential maintaining unit is electrically connected with the second control node, a second control terminal of the second potential maintaining unit is electrically connected with a second clock signal line, an input terminal of the second potential maintaining unit is electrically connected with a fourth level signal line, and an output terminal of the second potential maintaining unit is electrically connected with the output terminal of the shift register;
wherein a polarity of a level signal outputted from the third level signal lines is identical to a polarity of a level signal outputted from the fourth level signal line, and an absolute value of the level signal outputted from the third level signal lines is greater than an absolute value of the level signal outputted from the fourth level signal line;
wherein the method comprises:
a first period in which the scan driving unit controls a potential of a first control node to turn on the first transistor;
a second period in which the first transistor is turned on to output the scanning signal from the scanning signal input line to the output terminal of the shift register;
a third period in which the reset unit controls a potential of the first control node to turn off the first transistor; and
a fourth period in which the first potential maintaining unit transmits a level signal from the third level single line to the first control node, the second potential maintaining unit transmits a level signal from the fourth level single line to the output terminal of the shift register, and the first transistor is maintained in a turned-off state.
